(19) United States
(12) Patent Application Publication
(10) Pub. No.: US 2017/0256649 A1
(43) Pub. Date: Sep. 7, 2017

(54) SEMICONDUCTOR DEVICE

(71) Applicant: Sharp Kabushiki Kaisha, Sakai City, Osaka (JP)

(72) Inventors: Yutaka TAKAMARU, Sakai City (JP); Takao SAITOH, Sakai City (JP); Yohsuke KANZAKI, Sakai City (JP); Keisuke IDE, Sakai City (JP); Seiji KENEKO, Sakai City (JP)

(21) Appl. No.: 15/529,044

(22) PCT Filed: Nov. 20, 2015
(86) PCT No.: PCT/JP2015/082669

§ 371 Date: May 23, 2017

(30) Foreign Application Priority Data
Nov. 28, 2014 (JP) 2014-241472

(51) Int. Cl. H01L 29/786; H01L 27/12; H01L 29/24; G02F 1/1333; G02F 1/1368

(52) U.S. Cl. CPC H01L 29/78642; G02F 1/133345; G02F 1/1368; H01L 29/7869; H01L 29/24; H01L 27/1225; G02F 1/136286

(57) ABSTRACT

A semiconductor device includes a first conductive film, an insulating film, a second conductive film, and a semiconductor film. The insulating film is formed above the first conductive film such that the first conductive film includes an exposed portion that is exposed. The second conductive film is formed above the insulating film such that sides of the second conductive film are close to the exposed portion of the first conductive film. The semiconductor film includes a channel region for electrically connecting the second conductive film to the first conductive film via the channel region. The semiconductor film is formed above the second conductive film and across the exposed portion of the first conductive film from at least one side to another.

### TECHNICAL FIELD

The present invention relates to a semiconductor device.

### BACKGROUND ART

A display panel included in a display device may include semiconductor devices such as thin film transistors (TFTs). The semiconductor devices may be categorized into a horizontal type and a vertical type. A horizontal type semiconductor device includes a pair of conductive films (electrodes) formed in the same layer and opposed to each other with a predefined gap therebetween. The conductive films are electrically connected to each other via a semiconductor film. The vertical type semiconductor device includes a pair of conductive films formed in an upper layer and a lower layer, respectively, with a predefined gap therebetween and electrically connected to each other via a semiconductor film.

Patent Document 1 discloses vertical type thin film transistors for driving a liquid crystal display and image sensors. Each of the thin film transistors includes a pair of conductive films formed to sandwich an insulating film. A portion of one of the conductive films is not covered with the insulating film. A semiconductor film is formed across the portion of one of the conductive films not covered with the insulating film above the other one of the conductive films. The conductive films of the vertical type thin film transistor (a semiconductor device) having such a configuration partially overlap each other in a plan view. A length of a channel can be adjusted by adjusting a thickness of the insulating film.

### RELATED ART DOCUMENT

### Patent Document

Patent Document 1: Japanese Unexamined Patent Application Publication No. S60-160171

### Problem to be Solved by the Invention

In the thin film transistors disclosed in Patent Document 1, to improve driving performances of the thin film transistors or to increase currents flowing through channels, the number of the thin film transistors may be increased or a width of one of the conductive films in each thin film transistor may be increased to increase a cross section of the channel so that the current flowing through the channel increases. However, by increasing the number of the thin film transistors, an occupied area of the thin transistors increases and thus an area for pixel electrodes in the display device may be limited.

In the vertical type semiconductor device, by increasing the width of one of the conductive films in the vertical type thin film transistor, an entire area of the other one of the conductive films may overlap one of the semiconductor films in the plan view. Namely, the conductive films no longer partially overlap each other and thus the channel cannot be formed. Therefore, the occupied area of the thin film transistors needs to be increased and thus the area for the pixel electrodes in the display device may be limited.

### DISCLOSURE OF THE PRESENT INVENTION

The present invention was made in view of the above circumstances. An object is to increase a current flowing through a channel without increasing an occupied area of a semiconductor device.

### Means for Solving the Problem

A semiconductor device includes a first conductive film, an insulating film, a second conductive film, and a semiconductor film. The insulating film is formed above the first conductive film such that the first conductive film includes an exposed portion that is not covered with the insulating film. The second conductive film is formed above the insulating film such that sides of the second conductive film are close to the exposed portion of the first conductive film. The semiconductor film includes a channel region for electrically connecting the second conductive film to the first conductive film via the channel region. The semiconductor film is formed above the second conductive film and across the exposed portion of the first conductive film from at least one side to another.

The semiconductor device is a vertical type semiconductor device including a channel formed between the first conductive film and the second conductive film formed above the first conductive film. In the vertical-type semiconductor device, the second conductive film is formed above the insulating film such that the sides of the second conductive film are close to the exposed portion of the first conductive film and the semiconductor film is formed above the second conductive film and across the exposed portion of the first conductive film from at least one side to another. Therefore, in the channel region, multiple channels extending from the first conductive film to the first conductive film in one direction are formed in multiple directions rather than one direction. According to the configuration, the same effect achieved by increasing a cross-sectional area of a channel can be achieved, that is, a current flowing through the channel can be increased, with an occupied area of the semiconductor device maintained. In a display device including the semiconductor device, when any one of the first conductive film and the second conductive film is connected to a pixel electrode, a current flowing through the pixel electrode can be increased with the occupied area of the semiconductor device maintained. Therefore, time for charging the pixel electrode can be reduced.

In the semiconductor device, the first conductive film may include a main portion and two branch portions that branch off from the main portion and extend in the same direction. The branch portions may include sides opposed to each other and close to the exposed portion of the first conductive film.

A two-dimensional configuration of the first conductive film for forming the channels in two different directions from the second conductive film to the first conductive film is provided.

The insulating film may include a hole through which the exposed portion of the first conductive film is exposed. The semiconductor film may entirely cover the hole.

According to the configuration, an entire edge of the hole is covered with the semiconductor film, that is, the channel region is formed around the hole for an entire circumference of the hole. Namely, a bundle of multiple channels extending from the second conductive film to the first conductive film in different directions from the edge of the hole to the inner side of the hole is formed. According to the configuration, the current flowing through the channel region can be effectively increased with the occupied area of the semiconductor device maintained.

End surfaces of the semiconductor film may be exposed to an etchant in a production process. When an end surface of the semiconductor film included in the channel is exposed to the etchant in the production process, a portion around the end surface is less likely to function as a channel. According to the configuration described earlier, end surfaces of the semiconductor film are located outside the hole. Namely, the end surfaces of the semiconductor film are not included in the channel. Therefore, a current can effectively flow through an entire area of the channel and thus variations in current-voltage characteristics of the semiconductor device when the semiconductor device is driven for multiple times can be reduced.

The semiconductor film may be made of oxide semiconductor.

The semiconductor film made of oxide semiconductor film has higher electron mobility in comparison to a semiconductor film made of amorphous semiconductor. Therefore, according to the configuration, the semiconductor device can have various functions.

In the above semiconductor device, the semiconductor film may include a low resistance region having an electric resistance lower than the channel region. The lower resistance region may cover any one of a portion of the first conductive film and a portion of the second conductive film.

By covering the portion of the first conductive film or the portion of the second conductive film, which may be exposed to the outside, with the low resistance portion, the exposed portion of the first conductive film can be protected from foreign substance (e.g., protected from liquid or dust) with the low resistance region.

The oxide semiconductor may contain indium (In), gallium (Ga), zinc (Zn), and oxygen (O). In this case, the oxide semiconductor may have a crystalline structure.

This configuration is preferable for increasing the number of functions of the semiconductor device.

### Advantageous Effect of the Invention

According to the present invention, the current flowing through the channel can be increased without increasing the occupied area of the semiconductor device.

### BRIEF DESCRIPTION OF THE DRAWINGS

FIG. 1 is a schematic cross-sectional view of a liquid crystal display device cut along a long-side direction according to a first embodiment.

FIG. 2 is a schematic plan view of a liquid crystal panel.

FIG. 3 is a schematic cross-sectional view schematically illustrating a cross-sectional configuration of the liquid crystal panel.

FIG. 4 is a plan view illustrating a two-dimensional configuration of a pixel in a display area of an array board.

FIG. 5 is a cross-sectional view of a TFT in a cross-sectional configuration along line V-V in FIG. 4.

FIG. 6 is a cross-sectional view of a contact hole in a cross-sectional configuration along line VI-VI in FIG. 4.

FIG. 7 is a plan view illustrating a two-dimensional configuration of a pixel in a display area of an array board in a modification of the first embodiment.

FIG. 8 is a cross-sectional view including a TFT and therearound and a pixel electrode in a cross-sectional configuration along line VIII-VIII in FIG. 7.

FIG. 9 is a plan view illustrating a two-dimensional configuration of a pixel in a display area of an array board according to a second embodiment.

FIG. 10 is a cross-sectional view including a TFT and a contact hole in a cross-sectional configuration along line X-X in FIG. 9.

FIG. 11 is a plan view illustrating a two-dimensional configuration of a portion of a semiconductor device according to the third embodiment.

FIG. 12 is a cross-sectional view illustrating channels of the semiconductor device in a cross-sectional configuration along line XII-XII in FIG. 11.

### MODE FOR CARRYING OUT THE INVENTION

### First Embodiment

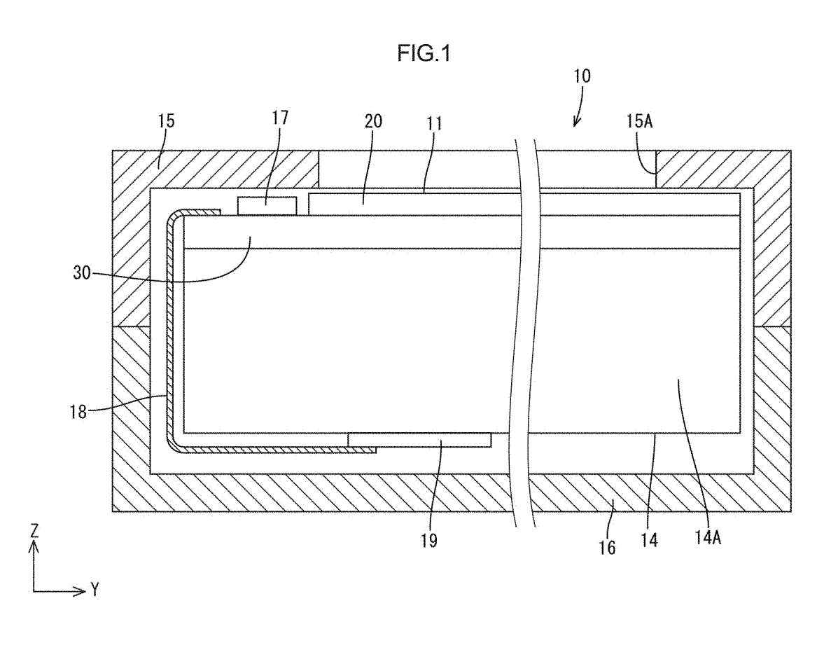

A first embodiment will be described with reference to FIGS. 1 to 6. In this section, a liquid crystal display device 10 including a liquid crystal panel 11 will be described. X-axis, Y-axis, and Z-axis may be present in FIGS. 1 to 6. The axes in each drawing correspond to the respective axes in other drawings. The vertical direction is based on FIG. 1. An upper side and a lower side in FIG. 1 correspond to a front side and a back side of the liquid crystal display device 10, respectively.

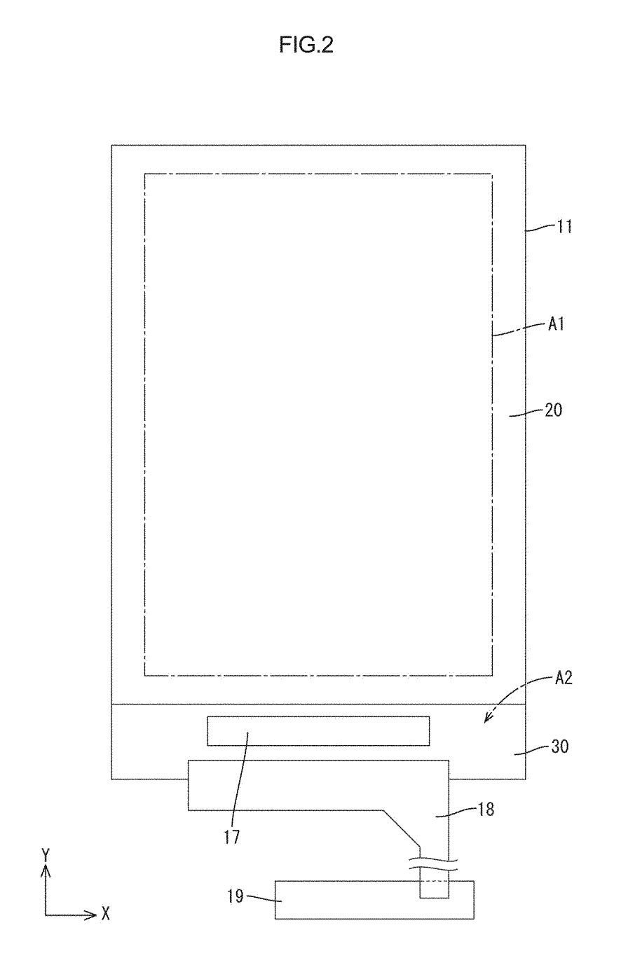

As illustrated in FIGS. 1 and 2, the liquid crystal display device 10 includes the liquid crystal panel 11, an IC chip 17, a control circuit board 19, a flexible circuit board 18, and a backlight unit 14. The IC chip 17 is an electronic component mounted on the liquid crystal panel 11 for driving the liquid crystal panel 11. The control circuit board 19 is for supplying various kinds of input signals from an external component to the IC chip 17. The flexible circuit board 18 electrically connects the liquid crystal panel 11 to the control circuit board 19 located outside. The backlight unit 14 is an external light source for supplying light to the liquid crystal panel 11. The liquid crystal display device 10 further includes a front exterior member 15 and a rear exterior member 16 assembled together for holding the liquid crystal panel 11 and the backlight unit 14 therein. The front exterior member 15 includes an opening 15A through which an image displayed on the liquid crystal panel 11 can be viewed from the outside.

First, the backlight unit 14 will be briefly described. As illustrated in FIG. 1, the backlight unit 14 includes a chassis 14A, a light source (such as cold cathode tubes, LEDs, and organic ELs), and an optical member. The chassis 14A has a substantially box shape with an opening on the front side. The light source, which is not illustrated, is disposed inside the chassis 14A. The optical member, which is not illustrated, is disposed to cover the opening of the chassis 14A. The optical member has a function for converting light emitted by the light source into planar light. The planar light obtained through the optical member enters the liquid crystal panel 11. The planar light is used for displaying an image on the liquid crystal panel 11.

Next, the liquid crystal panel 11 will be described. As illustrated in FIG. 2, the liquid crystal panel 11 has a vertically-long rectangular overall shape with a long-side direction and a short-side direction correspond with the Y-axis direction and the X-axis direction in each drawing, respectively. A large area of the liquid crystal panel 11 is a display area A1 in which images are displayed. An area close to one of ends in the long-side direction (the lower side in FIG. 2) is a non-display area A2 in which images are not displayed. The IC chip 17 and the flexible circuit board 18 are mounted to portions of the non-display area A2. As illustrated in FIG. 1, in the liquid crystal panel 11, the display area A1 has a frame shape slightly smaller than a color filter board 20, which will be described layer, indicated with a chain line. An area outside the chain line is the non-display area A2.

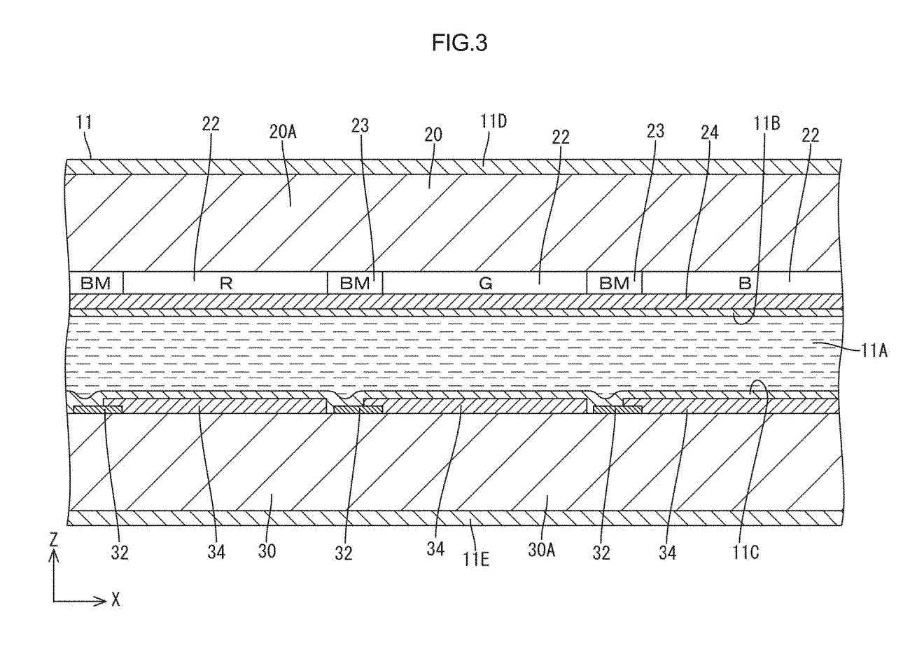

As illustrated in FIG. 3, the liquid crystal panel 11 includes a pair of glass boards 20 and 30 having high light transmissivity and a liquid crystal layer 11A including liquid crystal molecules. The liquid crystal molecules are substances having optical characteristics that change according to application of an electric field. The boards 20 and 30 in the liquid crystal panel 11 are bonded together with a sealing member, which is not illustrated, with a cell gap corresponding with a thickness of the liquid crystal layer 11A maintained therebetween. One of the boards 20 and 30 on the front side is the color filter board 20 and the other one on the rear side (on the back side) is an array board 30. Alignment films 11B and 11C are formed on inner surfaces of the boards 20 and 30, respectively, for alignment of the liquid crystal molecules in the liquid crystal layer 11A. The boards 20 and 30 include glass substrates 20A and 30A that are substantially transparent. Polarizing plates 11D and 11E are attached to outer surfaces of the glass substrates 20A and 30A, respectively.

As illustrated in FIG. 2, the color filter board 20 of the boards 20 and 30 have a short dimension about equal to a short dimension of the array board 30 and a long dimension smaller than a long dimension of the array board 30. The color filter board 20 is bonded to the array board 30 with one of ends with respect to the long-side direction (the upper side in FIG. 2) aligned with an end of the array board 30. The other end of the color filter board 20 with respect to the long-side direction (the lower side in FIG. 1) does not overlap a certain end area of the array board 30 with respect to the long-side direction. A front plate surface and a rear plate surface of the array board 30 in the certain end area are exposed to the outside. The certain end area is a mounting area for the IC chip 17 and the flexible circuit board 18. The color filter board 20 and the polarizing plate 11E are bonded to a major portion of the glass substrate 30A of the array board 30. A portion including the mounting area for the IC chip 17 and the flexible circuit board 18 does not overlap the color filter board 20 and the polarizing plate 11E.

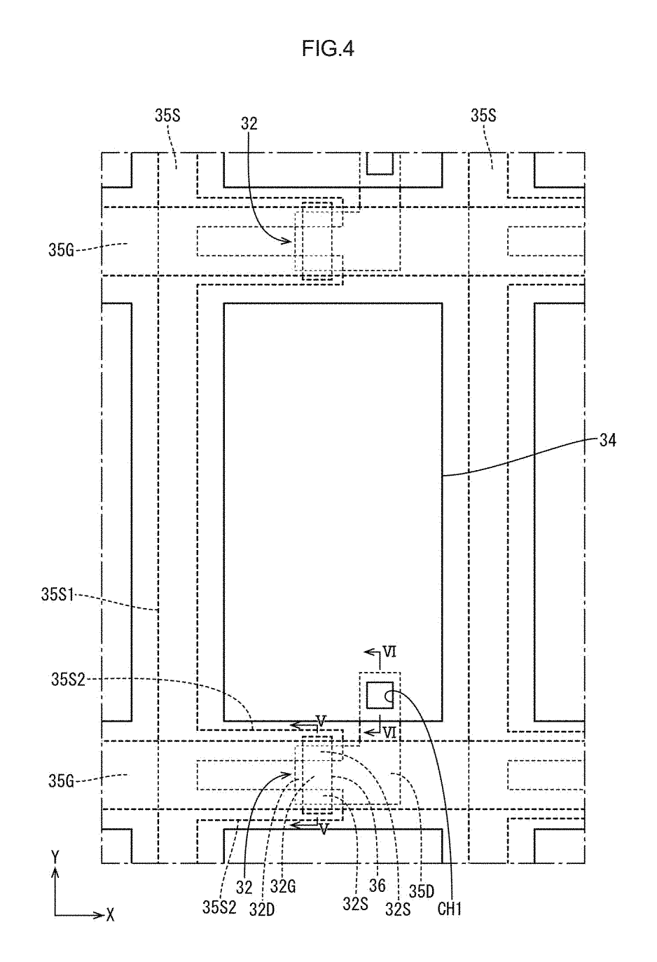

Next, configurations of the array board 30 and the color filter board 20 inside the display area A1 will be described. Multiple thin film patterns are layered on the inner surface of the glass substrate 30A in the array board 30 (on a liquid crystal layer 11A side). As illustrated in FIGS. 3 and 4, a large number of TFTs 32 (an example of the semiconductor device) and a large number of pixel electrodes 34 arranged in a matrix. Each of the TFTs 32 is a switching component including three electrodes 32G 32S, and 32D. Each of the pixel electrodes 34 is formed from a transparent conductive film made of indium tin oxide (ITO) and connected to a drain electrode 32D of the corresponding TFT 32, which will be described later.

As illustrated in FIG. 3, gate lines 35G and source lines 35S (an example of a second conductive film) are routed in a grid to surround the TFTs 32 and the pixel electrodes 34 in the array board 30. The gate lines 35G extend along the X-axis direction and the source lines 35S extend along the Y-axis direction. The gate lines 35G and the source lines 35G are perpendicular to each other. As illustrated in FIG. 3, each of the pixel electrodes 34 having a vertically-long rectangular shape in a plan view is formed in an area surrounded by the gate lines 35G and the source lines 35S. The drain lines 35D, which will be described later, are routed in portions around the pixel electrodes 34.

The array board 30 includes capacitive lines (not illustrated) parallel to the gate lines 35G and overlap the pixel electrodes 34 in the plan view. The capacitive lines and the gate lines 35 are alternately arranged with respect to the Y-axis direction. The gate lines 35G are arranged between the pixel electrodes 34 adjacent to each other with respect to the Y-axis direction. The capacitive lines are arranged to cross about the middle of the respective pixel electrodes 34 with respect to the Y-axis direction. The array board 30 includes terminals continuing from the gate lines 35G and the capacitive lines and terminals continuing from the source lines 35S. Signals or reference potentials from the control circuit board 16 illustrated in FIG. 1 are input to the terminals to control driving of the TFTs 32.

As illustrated in FIG. 2, the color filter board 20 includes a large number of color filters 22 arranged in a matrix on the inner surface of the glass substrate 20A (on the liquid crystal layer 11A side). The color filters 22 are arranged at positions that overlap the pixel electrodes 34 in the array board 30 in the plan view. The color filters 22 include red (R), green (G), and blue (B) color portions. A light blocking portion (a black matrix) 23 having a grid shape is formed among the color portions of the color filters 22 to reduce color mixture. The light blocking portion 23 is arranged to overlap the gate lines 35G, the source lines 35S, and the capacitive lines of the array board 30 in the plan view.

In the liquid crystal panel 11, each display pixel, which is a unit of display, includes the red (R) color portion, the green (G) color portion, the blue (B) color portion, and the pixel electrodes 34 opposed to those color portions, respectively. The display pixel includes a red pixel including the R color portion, a green pixel including the G color portion, and a blue pixel including the B color portion. Color pixels are repeatedly arranged along a row direction (the X-axis direction) on a plate surface of the liquid crystal panel 11 to form lines of pixels. Multiple lines of pixels are arranged along a column direction (the Y-axis direction).

As illustrated in FIG. 2, common electrodes 24 are formed on inner surfaces of the color filters 22 and the light blocking portion 23. The common electrodes 24 are opposed to the pixel electrodes of the array board 30. The common electrodes 24 are formed from a transparent conductive film made of ITO similar to the pixel electrodes 34. In the non-display area A2 of the liquid crystal panel 11, common electrode line, which are not illustrated, are routed and connected to the common electrodes 24 via contact holes, which are not illustrated. A reference potential is applied to the common electrodes 24 through the common electrode lines. By controlling the potentials applied to the pixel electrodes 34 by the TFTs 32, predefined potential differences are produced between the pixel electrodes 34 and the common electrodes 24.

Next, the TFTs 32 that are switching components of the array board 30 will be described in detail. As illustrated in FIG. 4, each source line 35S includes a main portion 35S1 and two branch portions 35S2. The main portion 35S1 extends perpendicular to the gate line 35G. The branch portions 35S2 branch off from the main portion 35S1 and extend in the same direction. The branch portions 35S2 are forked at a point at which the source line 35S crosses the gate line 35G. The branch portions 35S2 extend parallel to the gate line 35G. Ends of the branch portions 35S2 are configured as source electrodes 32S (an example of the second conductive film) of the TFT 32. A portion of the gate line 35G overlapping the source electrodes 32S in the plan view is configured as a gate electrode 32G of the TFT 32. The TFT 32 is formed such that the gate electrode 32G is the highest layer and the rest is below the gate electrode 32G. The gate lines 35G and the gate electrodes 32G are formed from a metal laminated film including metal films of tungsten (W) and silicon nitride (SxNx) which are layered.

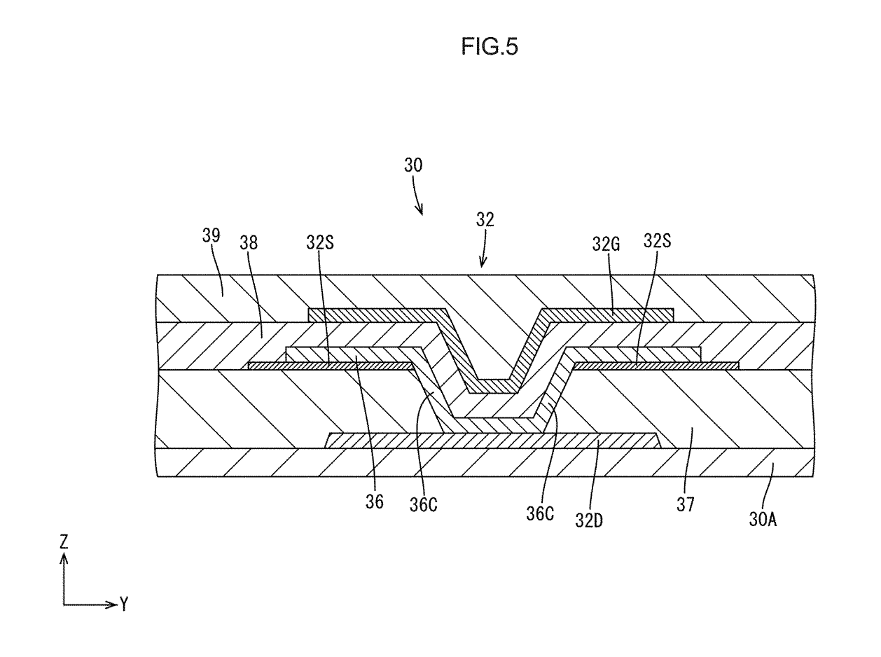

Each TFT 32 includes a drain electrode 32D (an example of the first conductive film) between two source electrodes 32S and below the source electrodes 32S. The drain electrode 32D is opposed to the source electrodes 32S with a predefined distance away from the source electrodes 32S in the vertical direction (the Z-axis direction). The drain electrode 32D is formed at a portion of the drain line 35D. As illustrated in FIG. 4, the drain line 35D extends from the TFT 32 along the gate line 35G and then toward the pixel electrode 34. A distal end of the drain line 35D overlaps a portion of the pixel electrode 34 in the plan view. A portion of the distal end of the drain line 35D on the TFT 32 is the drain electrode 35D. The source lines 35S, the source electrodes 32S, and the drain electrodes 32D are made from a multi-layer metal film having a three-layer structure including a titanium (Ti) layer, an aluminum (Al) layer, and a titanium layer in this sequence from the lower layer side. As illustrated in FIG. 5, in each TFT 32, a semiconductor film 36 is formed across the drain electrode 32D and the source electrode 32S. The semiconductor film 36 is made of amorphous silicon (a-Si) semiconductor or transparent amorphous oxide (InGaZnOx) semiconductor. The semiconductor film 36 functions as a channel for establishing electrical connection between the drain electrode 32D and the source electrode 32S.

The array board 30 includes different kinds of insulating films including a first insulating film 37 (an example of an insulating film), a gate insulating film 38, and a second insulating film 39 formed in layers in this sequence from the lower layer side (a glass substrate 30A side). As illustrated in FIG. 5, the first insulating film 37 is formed above the drain electrode 32D such that the drain electrode 32D includes an exposed portion that is not covered with the first insulating film 37. The gate insulating film 38 and the first insulating film 27 are made of the same material. The gate insulating film 38 is formed above the source line 35S, the source electrode 32S, and the semiconductor film 36 to insulate the gate electrode 32G from the semiconductor film 36. The second insulating film 39 is formed above the gate lines 35G and the gate electrode 32G. The first insulating film 37, the gate insulating film 38, and the second insulating film 39 are made of transparent inorganic materials. Specifically, the first insulating film 37 and the gate insulating film 38 are made of silicon oxide (SiOx). The second insulating film 39 is made of acrylic resin that is an organic material (e.g., polymethylmethacrylate resin (PMMA)) or polyimide resin.

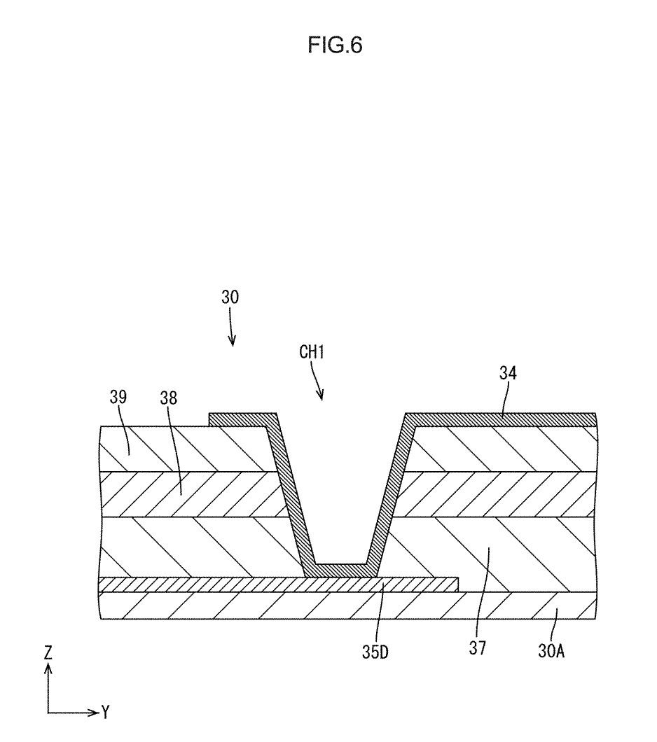

As illustrated in FIGS. 4 and 6, the first insulating film 37, the gate insulating film 38, and the second insulating film 39 include contact holes CH1 at positions overlapping the end portions of the drain electrodes 32D extending from the TFTs 32 in the plan view. The contact holes CH1 are through holes open in a top-bottom direction. The drain electrodes 32D are viewed through the contact holes CH1. The pixel electrodes 34 are formed in some areas above the second insulating film 39 across the contact holes CH1. The pixel electrodes 34 are connected to the drain electrodes 32D via the contact holes CH1.

As illustrated in FIGS. 4 and 5, in each TFT in this embodiment, two source electrodes 32S are formed on the first insulating film 37 such that sides of the source electrodes 32S opposed to each other with respect to the Y-axis direction are close to the exposed portion of the drain electrode 32D which is not covered with the first insulating film 37. Namely, the source electrodes 32S are formed on portions of the first insulating film 37 on the respective sides of the exposed portion of the drain electrode 32D which is not covered with the first insulating film 37. The source electrodes 32S are adjacent to the exposed portion of the drain electrode 32D which is not covered with the first insulating film 37 in the plan view. The source electrodes 32S are located close to the exposed portion of the drain electrode 32D which is not covered with the first insulating film 37 via the first insulating film 37.

The semiconductor film 36 extends from one side of the exposed portion of the drain electrode 32D which is not covered with the first insulating film 37 to the other side of the exposed portion of the drain electrode 32D. Namely, portions of the semiconductor film 36 on sidewall surfaces of the first insulating film 37 continue from the portions of the semiconductor film 36 formed on the respective source electrodes 32S and to portions of the semiconductor film 36 on the exposed portion of the drain electrode 32D which is not covered with the first insulating film 37. The source electrodes 32S are connected to the exposed portion of the drain electrode 32D which is not covered with the first insulating film 37 via the single semiconductor film 36. Because the source electrodes 32S are opposed to the drain electrode 32D with the predefined gap therebetween, the source electrodes 32S are not directly electrically connected to the drain electrode 32D. However, the source electrodes 32S are indirectly electrically connected to the drain electrode 32D via the semiconductor film 36. Therefore, a bridge portion of the semiconductor film 36 between the electrodes 32D and 32S functions as channel regions 36C through which a drain current flows (see FIG. 5).

Each TFT 32 includes two current paths. In the plan view of FIG. 4, a path in which a drain current flows from one of the source electrodes 32S (the source electrode 32S located on the lower side in FIG. 4) to the exposed portion of the drain electrode 32D is one of the current paths. A path in which a drain current flows from the other source electrode 32S (the source electrode 32S located on the upper side in FIG. 4) to the exposed portion of the drain electrode 32D is the other current path. In comparison to a configuration including a single drain current path, the driving performance of the TFT 32 in this embodiment is improved.

To form the two current paths for the drain currents to be passed to a single pixel electrode 34, two TFTs 32 may be provided or a width of the source electrodes 32S may be increased. If two TFTs 32 are provided, an area of the surface of the array board 30 occupied by the TFTs 32 per single pixel electrode 34 increases. Therefore, an area for the pixel electrode 34 is limited. Because the TFT 32 is a vertical-type semiconductor device, as illustrated in FIG. 4, the electrodes 32S and 32D partially overlap in the plan view as illustrated in FIG. 4. If the width of the source electrodes 32S is increased, the source electrodes 32S cover the entire area of the drain electrode 32D in the plan view. Namely, the electrodes 32S do not partially overlap the electrode 32D and thus the channels are not provided. Therefore, the occupied area of the TFT 32 needs to be increased and thus the area for the pixel electrode 34 is limited.

In the TFT 32 in this embodiment, two current paths through which the drain currents flow are provided without forming two TFTs 32 or increasing the width of the source electrodes 32S. Namely, channels that extend in two directions from the respective source electrodes 32S to the drain electrode 32D are provided. In the liquid crystal display device 10, the current flowing through the channel region increases with the occupied area of the TFT 32 maintained. This is the same effect as in the case that the cross-sectional area of the channel is increased. Therefore, time for charging the pixel electrode 34 can be decreased. In the TFT 32 in this embodiment, the semiconductor film 36 continues through the sidewall surfaces of the first insulating film 37. By adjusting the thickness of the first insulating film 37, the length of the channel can be adjusted.

### Modification of the First Embodiment

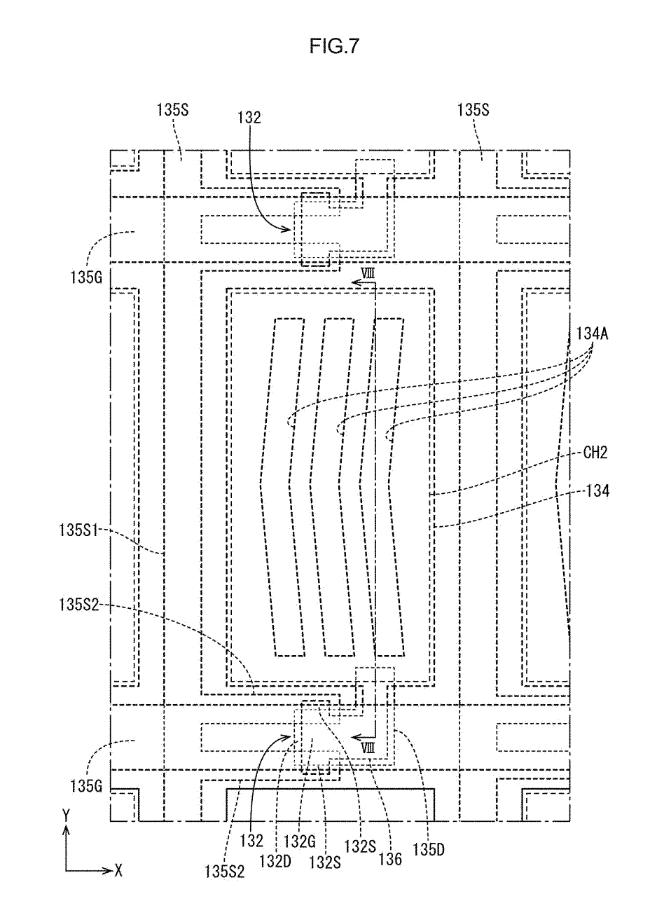

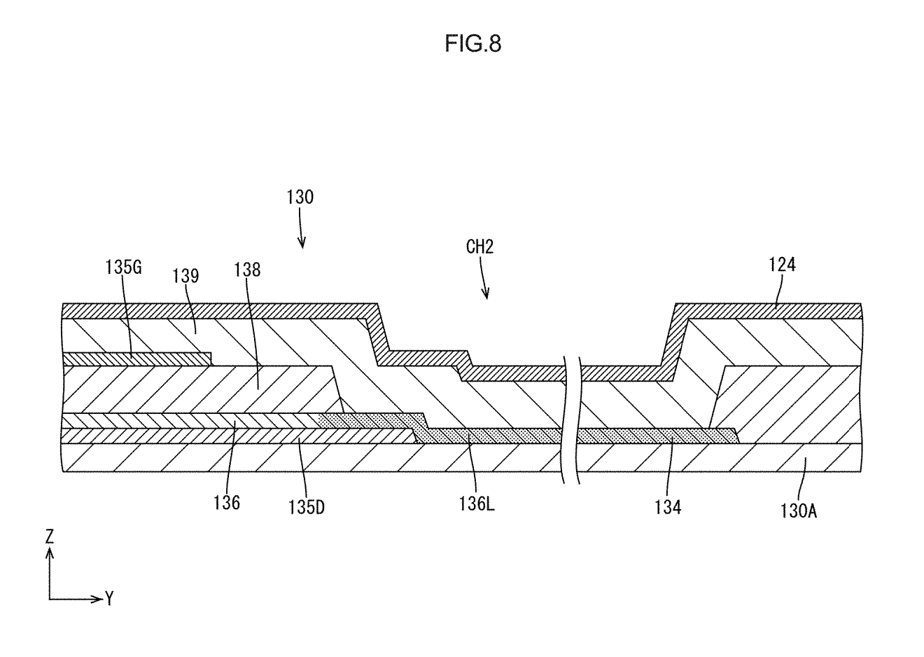

A modification of the first embodiment will be described with reference to FIGS. 7 and 8. A liquid crystal panel in this modification operates in fringe field switching (FFS) mode. An array board 130 (see FIG. 8) in the liquid crystal panel includes pixel electrodes 134 and common electrodes 124. The pixel electrodes 134 and the common electrodes 124 are formed in different layers with an insulating film therebetween. In this modification, the pixel electrode 134 in each pair of the electrodes 124 and 134 is located in the lower layer and the common electrode 124 is located in the upper layer. Configurations of the TFTs 132, portions around the TFTs 132, and functions in this modification different from the first embodiment will be described below.

The pixel electrodes 134 are formed by reducing resistance of semiconductor films 136 that form portions of the TFTs 132. As illustrated in FIG. 7, pixel electrodes 134 are formed in entire areas surrounded by gate lines 135G and source lines 135S. Each pixel electrode 134 has a vertically-long rectangular shape in a plan view. The common electrodes 124 are formed in a solid pattern in the upper layer such that each common electrode 124 covers multiple pixel electrodes 13 (not illustrated in FIG. 7). A portion of each pixel electrode 134 surrounded by the gate lines 135G and the source lines 135S includes three vertically-long bent slits (hereinafter referred to as “slits 134A”). Slits 134A are formed at predefined intervals along the source lines 135S in each pixel.

Reference voltages are applied to the common electrodes 124 via common electrode lines. By adjusting potential applied to the pixel electrodes 134 by the TFTs 132, predefined potential differences are produced between the pixel electrodes 134 and the common electrodes 124. When the potential differences are produced between the electrodes 124 and 134, fringe electric fields (oblique electric fields) including components along a plate surface of the array board 130 and components perpendicular to the plate surface of the array board 130 are applied to a liquid crystal layer because of the slits 134A of the pixel electrodes 134. According to the configuration, not only orientation of liquid crystal molecules in the liquid crystal layer above the slits 134A but also orientation of liquid crystal molecules on the common electrodes 124 can be properly adjusted. In the liquid crystal panel in this modification, an aperture ratio increases and thus a sufficient amount of transmitting light can be obtained and high viewing angle performances can be achieved.

In this modification, the semiconductor films 136 are made of oxide semiconductor. As illustrated in FIGS. 7 and 8, each semiconductor film 136 extends outer than the TFT 132 and a portion of the semiconductor film 136 forms the pixel electrode 134. A portion of the semiconductor film 136 is configured as a low resistance region 136L by reducing the resistance of the oxide semiconductor. The low resistance region 136L is the pixel electrode 134. A gate insulating film 138 formed above the semiconductor film 136 includes second contact holes CH2. Portions of the semiconductor films 136 in the second contact holes CH2, specifically, the pixel electrodes 134 are exposed.

As illustrated in FIG. 7, an end portion of a drain electrode 132D slightly overlaps an end portion of the pixel electrode 134. The drain electrode 132D is electrically connected to the low resistance region 136L of the pixel electrode 134. When a gate electrode 132G of the TFT 132 conducts (the TFT 132 turns on), a current flows between a source electrode 132S and the drain electrode 132D via two channel regions 136C. A predefined voltage is applied to the pixel electrode 134.

The oxide semiconductor used for the semiconductor film 136 may be a transparent indium-gallium-zinc-oxide (In—Ga—Zn—O) based semiconductor containing indium (In), gallium (Ga), zinc (Zn), and oxygen (O). The In—Ga—Zn—O based semiconductor is a ternary oxide of indium (In), gallium (Ga), and zinc (Zn). A ratio of In, Ga, and Zn (a composition ratio) is not specified. Examples of the ratio include In:Ga:Zn=2:2:1, In:Ga:Zn=1:1:1, and In:Ga:Zn=1:1:2. The oxide semiconductor (the In—Ga—Zn—O base semiconductor) of the semiconductor film 136 may have an amorphous structure but preferably have a crystalline structure including crystalline portions. The oxide semiconductor having a crystalline structure is preferably a crystalline In—Ga—Zn—O based semiconductor with a c-axis substantially perpendicular to a layer surface. Such a crystalline structure of the oxide semiconductor (the In—Ga—Zn—O based semiconductor) is disclosed in Unexamined Japanese Patent Application Publication No. 2012-134475. All contents of Unexamined Japanese Patent Application Publication No. 2012-134475 are incorporated herein by reference.

The oxide semiconductor of the semiconductor film 136 has electron mobility 20 to 50 times higher than electron mobility of an amorphous silicon thin film. Therefore, a size of the TFT can be easily reduced and the amount of transmitting light through the pixel electrode 134 can be maximized. This is preferable for improving definition of the liquid crystal panel and reducing power consumption of the backlight unit. Because the channel regions 136C are made of oxide semiconductor, turn-off characteristics of the TFT 132 are higher than a channel made of amorphous silicon and thus an off-leak current may be 1/100. The pixel electrode 134 has high voltage retention rate. This is preferable for reducing power consumption of the liquid crystal panel.

Next, a method of forming the low resistance region 136L in the portion of the semiconductor film 136 made of the oxide semiconductor will be briefly described. In this modification, a second insulating film 139 formed above the semiconductor film 136 is made of silicon nitride. In a production process of the array board 130, the second insulating film 139 is formed above the semiconductor film 136. The portion of the semiconductor film 136 in the second contact hole CH2 and exposed contacts the second insulating film 139. As a result, the resistance of the contact area and therearound is reduced and the low resistance region 136L is prepared. The silicon nitride of the second insulating film 139 includes Si—H bonding. When the second insulating film 139 contacts a portion of the semiconductor film 136, hydrogen is released from the Si—H bonding and diffused in the contact area of the semiconductor film 136. The contact area of the semiconductor film 136 is reduced due to strong reduction action of the hydrogen and the resistance of the contact area is reduced. The low resistance region 136L is formed in the portion of the semiconductor film 136. A sheet resistance of the low resistance region 136L formed as described above may be 1 kΩ/□ or lower.

In this modification, the liquid crystal panel that operates in FFS mode is provided. Similar to the first embodiment, in the liquid crystal panel, two current paths through which the drain currents flow are formed without forming two TFTs 132 or increasing the width of the source electrodes 132S. Therefore, the current flowing through the channel region can be increased without increasing the occupied area of the TFT 132. In this modification, the low resistance region 136L is formed in the portion of the semiconductor film 136 and the low resistance region 136L is configured as the pixel electrode 134. Therefore, it is not required to form the pixel electrode 134 in the production process of the liquid crystal panel and thus the production cost can be reduced.

### Second Embodiment

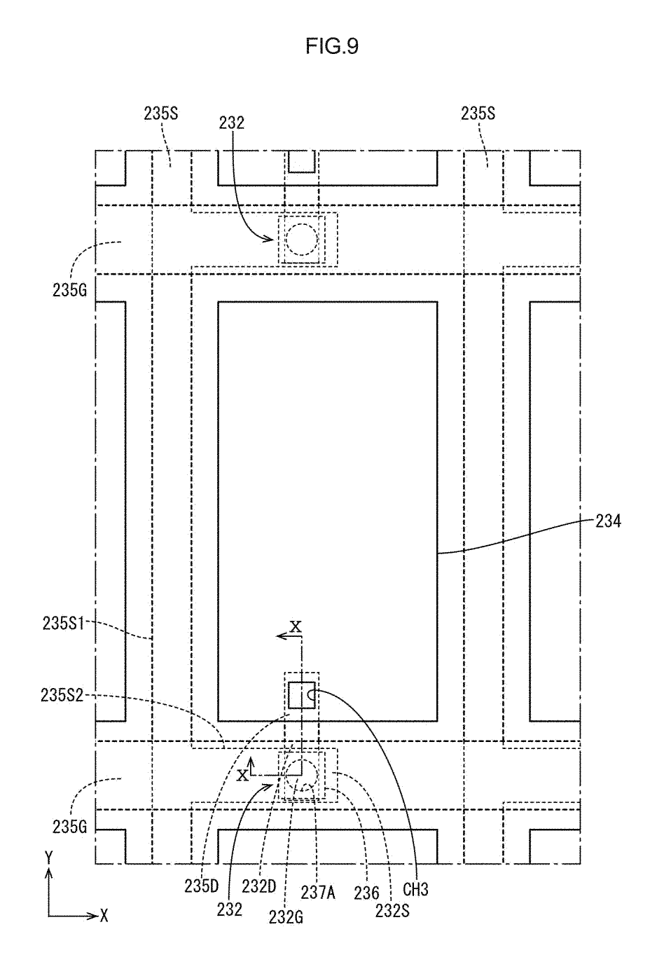

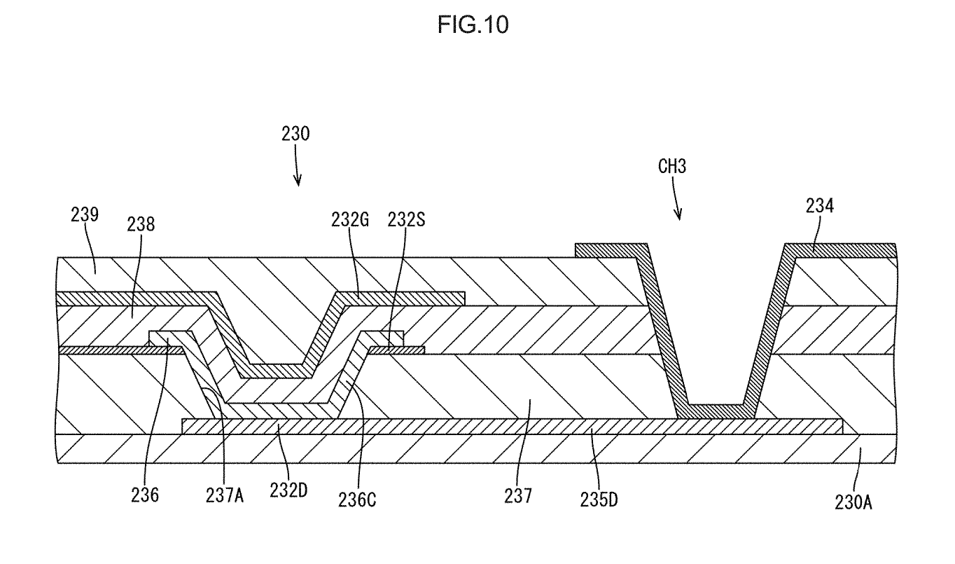

A second embodiment according to the present invention will be described with reference to FIGS. 9 and 10. The second embodiment includes TFTs 232 having a configuration different from the first embodiment. As illustrated in FIG. 9, each TFT 232 in this embodiment includes a source line including a main portion 235S1 and a branch portion 235S2. The main portion 235S1 is perpendicular to a gate line 235G. The branch portion 235S2 branches off the main portion 235S1 and extends in the same direction. The branch portion 235S2 branches off from a portion that crosses the gate line 235G and extends parallel to the gate line 235G with a width about equal to the width of the gate line 235G. A distal end of the branch portion 235S2 is configured as a source electrode 232S of the TFT 232.

As illustrated in FIG. 9, the TFT 232 in this embodiment includes a first insulating film 237 including a hole 237A having a round shape in a plan view. A portion of a drain electrode 232D is exposed through the hole 237A. The source electrode 32S is formed on the first insulating film 237 close to an edge of the hole 237A in the first insulating film 237 (see FIG. 10). A semiconductor film 236 is formed to entirely cover the hole 237A in the first insulating film 237 in the plan view. Portions of the semiconductor film 236 on surfaces of sidewalls of the first insulating film 237 continue from portions on the source electrode 232S and to a portion of the semiconductor film 236 on the exposed portion of the drain electrode 232D which is not covered with the first insulating film 237. Namely, the semiconductor film 236 is formed in an inverted cone shape to cover the exposed portion of the drain electrode 232D in all directions from a circumference.

The source electrode 232S is connected to the exposed portion of the drain electrode 232D in all directions of the exposed portion of the drain electrode 232D from the circumference via a single semiconductor film 236. The source electrode 232S and the drain electrode 232D are opposed to each other with a predefined gap therebetween and thus not directly electrically connected to each other. However, as described above, the source electrode 232S and the drain electrode 232D are indirectly electrically connected to each other via the semiconductor film 236. A bridge portion of the semiconductor film 236 between the electrodes 232S and 232D functions as a channel region 236C through which a drain current flows (see FIG. 10).

In the TFT 232 having such a configuration, the semiconductor film 236 covers an entire hole edge of the hole 237A in the first insulating film 237. The channel region is formed in the entire area around the hole 237A. The channel region is a bundle of channels that extend from the drain electrode 232D to the source electrode 232S in directions from the outer side to the inner side of the hole 237A in the first insulating film 237. According to the configuration, the current flowing through the channel region can be effectively increased with the occupied area of the TFT 232 maintained.

End surfaces of the semiconductor film 236 are exposed to an etchant in the production process. When an end surface of the semiconductor film 236 included in the channel is exposed to the etchant in the production process, a portion around the end surface does not function as a channel and thus the drain current is less likely to flow through the portion around the end surface. In the TFT 232 in this embodiment, end surfaces of the semiconductor film 236 are located outside the hole 237A in the first insulating film 237. Namely, the end surfaces of the semiconductor film 236 are not included in the channel. Therefore, a current can effectively flow through an entire area of the channel and thus variations in current-voltage characteristics of the TFT 232 when the TFT 232 is driven for multiple times can be reduced.

### Third Embodiment

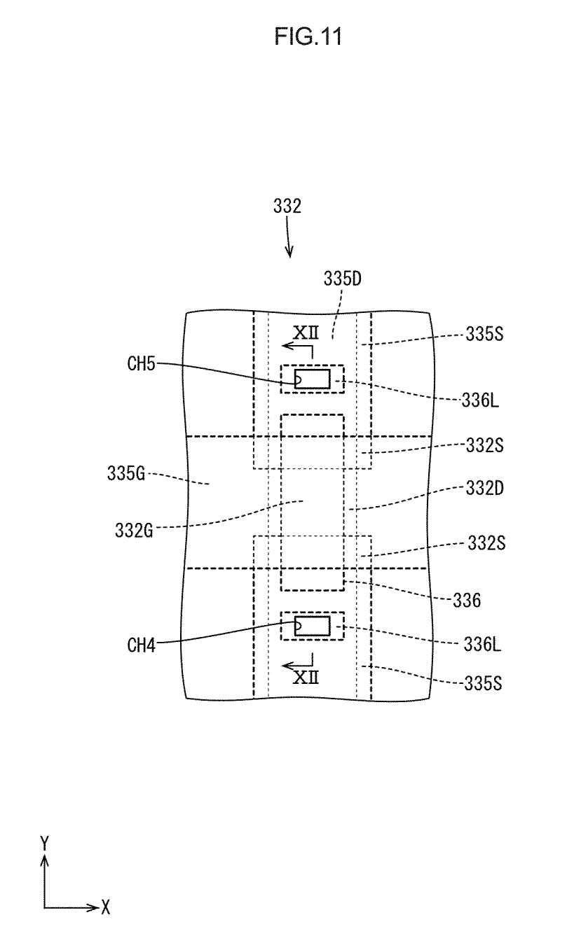

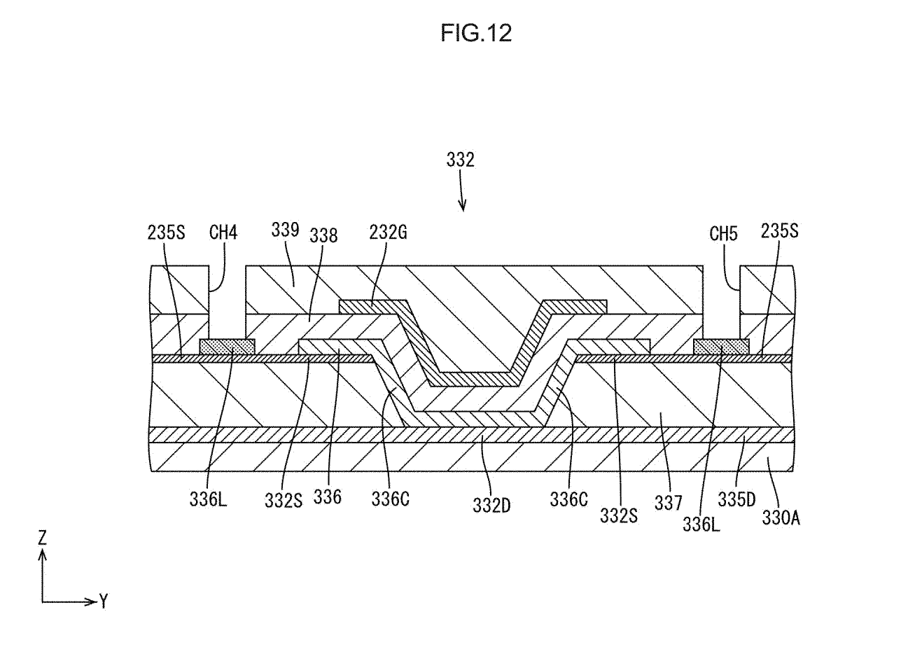

A third embodiment according to the present invention will be described with reference to FIGS. 11 and 12. The third embodiment includes vertical-type TFTs 332 illustrated in FIGS. 11 and 12. The TFTs 332 are formed on a substrate 330A (see FIG. 12). As illustrated in FIG. 11, each TFT 332 includes a gate line 335G and two source lines 335S. The gate line 335G extends along the X-axis direction. The source lines 335S extend along the Y-axis direction and include end portions opposed to each other with a predefined gap therebetween. The TFT 332 further includes a drain line 335D below the source line 335S. The drain line 335D extends along the Y-axis direction and overlaps the source line 335S in a plan view. In the TFT 332, the gate line 335G crosses the end portions of the source lines 335S and a portion of the drain line 335D.

The end portions of the source lines 335S opposed to each other are configured as source electrodes 332S of the TFT 332. The portion of the drain line 335D overlapping the gate line 335G is configured as a drain electrode 332D of the TFT 332. As illustrated in FIGS. 11 and 12, a semiconductor film 336 if formed to extend between the electrodes 332D and 332S. The semiconductor film 336 functions as a channel for establishing electrical connection between the drain electrode 332D and the source electrode 332S.

As illustrated in FIG. 12, different kinds of insulating films are formed in layers on the substrate 330A. The insulating films include a first insulating film 337, a gate insulating film 338, and a second insulating film 339 formed in this sequence from a lower layer side. As illustrated in FIG. 12, the first insulating film 337 is formed above the drain electrode 332D to such that the drain electrode 332D includes an exposed portion that is not covered with the first insulating film 337. The gate insulating film 338 is formed above the source lines 35S, the source electrodes 332S, and the semiconductor film 336 for insulating a gate electrode 332G from the semiconductor film 336. The second insulating film 339 is formed above the gate line 335G and the gate electrode 332G.

In the TFT 332, the source electrodes 332S are formed on the first insulating film 337 such that the sides of the source electrodes 332S are close to the exposed portion of the drain electrode 332D with respect to the Y-axis direction. The semiconductor film 336 is formed across the exposed portion of the drain electrode 332D. The source electrodes 332S are connected to the exposed portion of the drain electrode 332D via the single semiconductor film 336. The bridge portions of the semiconductor film 336 between the electrodes 332D and 332S functions as a channel regions 336C (see FIG. 12) through which the drain currents flow.

In the TFT 332, two low resistance regions 336L are formed in portions of the semiconductor film 336 by reducing resistance of the oxide semiconductor. The low resistance regions 336L overlap portions of the source line 335S outside the TFT 332. The low resistance regions 336L are opposed to the semiconductor film 336 inside the TFT 332 with a predefined gap therebetween. The low resistance regions 336L cover portions of the source electrodes 332S. The gate insulating film 338 and the second insulating film 339 include contact holes CH4 and CH5, respectively. The contact holes CH4 and CH5 are through holes formed at positions that overlap the low resistance regions 336L in a plan view. The low resistance regions 336L are exposed through the contact holes CH4 and CH5.

The TFT 332 having such a configuration includes two current paths. One of the current paths passes a drain current from one of the source electrodes 332S to the exposed portion of the drain electrode 332D. The other one of the current paths passes a drain current from the other one of the source electrodes to the exposed portion of the drain electrode 332D. Namely, the TFT 332 includes two channels that extend from the respective source electrodes 332S to the drain electrode 332D in different directions. According to the configuration, the current flowing through the channel region increases with the occupied area of the TFT 332 maintained.

In the TFT 332 in this embodiment, the portions of the source electrodes 332S exposed through the contact holes CH4 and CH5 are covered with a low resistance regions 335L. Therefore, the exposed portions of the source electrodes 332S are protected from foreign substance (e.g., protected from liquid or dust) with the low resistance regions 336L.

Modifications of the above embodiment are listed below.

(1) In each of the above embodiments, each TFT includes the channels that extend in two different directions from the respective source electrodes to the drain electrode or the bundle of multiple channels extending from one source electrode to the drain electrode in different directions from the edge of the hole in the first insulating film to the inner side of the hole. However, the number of the source electrodes and the channels in each TFT or the directions in which the channels are formed are not limited to those of the above embodiments.

(2) In the modification of the first embodiment, the low resistance regions are configured as the pixel electrodes. However, the low resistance regions may be configured as the common electrodes. In this case, the transparent electrode film formed on the second insulating film may be configured as the pixel electrodes.

(3) In each of the above embodiments, the TFTs are provided as an example of the semiconductor device. However, the semiconductor device is not limited to the TFTs.

The embodiments described above in detail are only examples and do not limit the scope of claims. Modifications of the above embodiments are included in the technical scope of claims.

### EXPLANATION OF SYMBOLS

10: liquid crystal display device, 11: liquid crystal panel, 11A: liquid crystal layer, 14: backlight unit, 20: color filter board, 30, 130, 230: array board, 32, 132, 232, 332: TFT. 32D, 132D, 232D, 332D: drain electrode, 32G, 132G, 232G, 332G: gate electrode, 32S, 132S, 232S, 332S: source electrode. 35D, 135D, 235D, 335D: drain lines, 35G, 135G, 235G, 335G: gate line, 35S, 135S, 235S, 335S: source line, 35S1, 135S1, 235S1: main portion, 35S2, 135S2, 235S2: branch portion, 36, 136, 236, 336: semiconductor film, 36C, 136C, 236C, 336C: channel region, 37, 137, 237, 337: first insulating film, 38, 138, 238, 338: gate insulating film, 39, 139, 239, 339: second insulating film, 136L, 336L: low resistance region, 237A: hole (in the first insulating film), 330: substrate, CH1, CH2, CH3, CH4, CH5: contact hole

1. A semiconductor device comprising:
a first conductive film;
an insulating film formed above the first conductive film such that the first conductive film includes an exposed portion that is not covered with the insulating film;
a second conductive film formed above the insulating film such that sides of the second conductive film are close to the exposed portion of the first conductive film; and
a semiconductor film including a channel region for electrically connecting the second conductive film to the first conductive film via the channel region, the semiconductor film being formed above the second conductive film and across the exposed portion of the first conductive film from at least one side to another.

2. The semiconductor device according to claim 1, wherein
the first conductive film includes a main portion and two branch portions that branch off from the main portion and extend in a same direction, and
the two branch portions include sides opposed to each other and close to the exposed portion of the first conductive film.

3. The semiconductor device according to claim 1, wherein
the insulating film includes a hole through which the exposed portion of the first conductive film is exposed, and
the semiconductor film entirely covers the hole.

4. The semiconductor device according to claim 1, wherein the semiconductor film is made of oxide semiconductor.

5. The semiconductor device according to claim 4, wherein
the semiconductor film includes a low resistance region having an electric resistance lower than the channel region, and
the low resistance region covers any one of a portion of the first conductive film and a portion of the second conductive film.

6. The semiconductor device according to claim 5, wherein the low resistance region is configured as a pixel electrode.

7. The semiconductor device according to claim 4, wherein the oxide semiconductor contains indium (in), gallium (Ga), zinc (Zn), and oxygen (O).

8. The semiconductor device according to claim 7, wherein the oxide semiconductor has a crystalline structure.
